(19) United States
(12) Patent Application Publication
(10) Pub. No.: US 2012/0300285 A1
(43) Pub. Date: Nov. 29, 2012

(54) ELECTRONIC PAPER DISPLAY DEVICE AND METHOD OF MANUFACTURING THE SAME

(75) Inventor: Seung Hyun RA, Gyeonggi-do (KR)

(73) Assignee: SAMSUNG ELECTRO-MECHANICS CO., LTD., Suwon (KR)

(21) Appl. No.: 13/455,787

(22) Filed: Apr. 25, 2012

(30) Foreign Application Priority Data
May 24, 2011 (KR) 10-2011-0049131

(51) Int. Cl. G02F 1/167; C23C 14/12; B05D 5/12

(52) U.S. Cl. 359/296; 427/77; 427/525

(57) ABSTRACT

Disclosed herein are an electronic paper display device including a lower electrode; twist balls provided in each cell of a barrier structure formed on the lower electrode; and an upper electrode provided above the twist balls and having an anti-reflection part provided on a surface thereof and having a moth-eye pattern, the surface facing the twist balls, and a method of manufacturing the same. According to the present invention, the upper electrode can be molded simultaneously with forming of the anti-reflection part rather than the anti-reflection coating film is formed on the upper electrode of the electronic paper display device through a separate process, thereby making it possible to simplify the manufacturing process of the upper electrode having the anti-reflection effects and reduce the manufacturing costs thereof, and improve productivity.

### CROSS REFERENCE(S) TO RELATED APPLICATIONS

This application claims the benefit under 35 U.S.C. Section 119 of Korean Patent Application Serial No. 10-2011-0049131, entitled “Electronic Paper Display Device and Method of Manufacturing the Same” filed on May 24, 2011, which is hereby incorporated by reference in its entirety into this application.

### BACKGROUND OF THE INVENTION

1. Technical Field

The present invention relates to an electronic paper display device and a method of manufacturing the same, and more particularly, to an electronic paper display in which an upper electrode thereof having anti-reflection effects can be manufactured in a simple structure and scheme, compared to an electronic paper display device according to the related art in which an anti-reflection coating film is formed on the upper electrode thereof, to thereby simplify a manufacturing process thereof, reduce manufacturing costs thereof, and further improve productivity, and a method of manufacturing the same.

2. Description of the Related Art

With the development of technology of a display, the use of displays such as a liquid crystal display (LCD), a plasma display panel (PDP), an electro luminescence, and the like have widely spread.

The development of technology of an electronic paper display device, which is called a digital paper display (DPD), has accelerated as the next generation display device following the foregoing display device. That is, an electronic paper, which is a flexibly bendable display device, has been prominent as a device that may replace the flat type display devices.

The electronic paper display device implements an ink effect by millions of twist balls and capsules injected into flexible substrates such as thin-type plastics to thereby allow characters or images to be displayed. The electronic paper display device does not require background lighting or continuous recharging as in the flat type display device, such that it may be driven with very low energy, and a result, provides significantly excellent energy efficiency.

The electronic paper display device has high definition and wide viewing angle and may also have a memory function that displays characters or images without fading away even if power is instantly blocked. As a result, the electronic paper display device is expected to be widely used in various fields such as bendable screens and electronic wall paper as well as printing media such as books, newspapers, magazines or the like.

Meanwhile, a technical scheme capable of developing and accomplishing the electronic paper display device is largely divided into a liquid crystal scheme, electro luminescence (EL) scheme, a reflective film reflective display scheme, an electrophoresis scheme, a twist ball scheme, an electochromic scheme, a mechanical reflective display scheme, and the like.

Among others, an electronic paper display device using twist balls is configured to include a substrate 2 having a lower electrode 1 formed thereon, a barrier structure 3 provided on the lower electrode 1, twist balls 4 provided in each cell of the barrier structure 3, and a glass 6 provided above the barrier structure 3 and having an upper electrode 5 formed on a lower surface thereof.

Therefore, in the electronic paper display device according to the related art, the twist ball 4 is rotated on an elastomer sheet by an electric field applied to the upper and lower electrodes 1 and 5 based on a dielectric liquid, such that characters or images are displayed due to a position arrangement of transparent or opaque segments provided based on a central portion of the twist ball 4.

In this configuration, the upper electrode 5 is formed of a transparent conductive film having electrical conductivity, that is, an indium tin oxide (ITO) thin film that is a film made of a compound of indium and tin oxide. At this time, the upper electrode 5 is subject to an anti-reflection treatment for increasing light transmittance of the surface thereof, that is, an interface with air.

The anti-reflection treatment is to form an anti-reflection film by depositing, in a thin film shape, a dielectric body having a small refractive index on the interface of the upper electrode 5 in a vacuum state by a sputtering scheme.

However, when the anti-reflection film is formed by a vacuum deposition process according to the related art, several deposition processes are to be repeated so as to form the anti-reflection film having a desired thickness and furthermore, the process of forming the anti-reflection film is performed through a separate vacuum after the manufacturing process of the upper electrode 5 is performed, such that the processing time is lengthened, the manufacturing costs thereof are increased, and furthermore, the productivity of the electronic paper display device including the same is degraded.

### SUMMARY OF THE INVENTION

An object of the present invention is to provide an electronic paper display device capable of molding an upper electrode simultaneously with forming an anti-reflection part to simplify a manufacturing process of the upper electrode having an anti-reflection effect and manufacturing costs thereof, and a method of manufacturing the same.

Another object of the present invention is to provide an electronic paper display device that simplifies the manufacturing process of the upper electrode to thereby reduce manufacturing costs and productivity thereof due to the process simplification of the electronic paper display device including the same, and a method of manufacturing the same.

According to an exemplary embodiment of the present embodiment, there is provided an electronic paper display device, including: a lower electrode; twist balls provided in each cell of a barrier structure formed on the lower electrode; and an upper electrode provided above the twist balls and having an anti-reflection part provided on a surface thereof and having a moth-eye pattern, the surface facing the twist balls.

The upper electrode may be formed of a transparent conductive film made of indium tin oxide (ITO) through which light is transmitted.

The upper electrode may be formed, in a sol-gel form, on one surface of glass.

The moth-eye pattern may have a nano size.

The moth-eye pattern may have a cone shape.

According to another exemplary embodiment of the present invention, there is provided a method of manufacturing an electronic paper display device, including: forming an anodic aluminum oxide (AAO) having a moth-eye pattern with a plurality of grooves by anodizing aluminum deposited on one surface of a substrate; coating a sol-gel on the AAO; bonding a transparent member to the sol-gel; and forming an upper electrode having the anti-reflection part having the moth-eye pattern with a plurality of projections on one surface of the transparent member by removing the substrate and the AAO.

The substrate may be formed of a flat glass.

The aluminum may be deposited on the substrate by a sputtering scheme or an e-beam scheme.

The moth-eye pattern may have a nano size and a cone shape.

The sol-gel may be prepared by mixing indium acetylacetonate, tin isopropoxide, and methosyethanol.

Spin coating may be performed on the sol-gel.

The spin coating may be performed in a vacuum state.

The method may further include annealing the sol-gel, after the bonding of the transparent member to the sol-gel.

The annealing of the sol-gel may be performed at a temperature of 400 to 800° C. for 30 to 60 minutes.

The annealing of the sol-gel may be performed under an atmosphere of an inert gas of argon (Ar) or nitrogen (N₂).

The removing of the AAO may be performed by an etching scheme after the substrate is removed.

The upper electrode may be formed of a transparent conductive film made of indium tin oxide (ITO) through which light is transmitted.

### BRIEF DESCRIPTION OF THE DRAWINGS

FIG. 1 is a cross-sectional view schematically showing an electronic paper display device according to the related art;

FIG. 2 is a cross-sectional view schematically showing an electronic paper display device according to the present invention; and

FIGS. 3 to 7 are diagrams for explaining a method of manufacturing an electronic paper display device according to the present invention, wherein:

FIG. 3 is a view showing a state in which aluminum is deposited on a substrate;

FIG. 4 is a view showing a state in which the aluminum deposited in FIG. 3 is anodized to thereby form an anodic aluminum oxide (AAO) on the substrate;

FIG. 5 is a view showing a state in which the AAO in FIG. 4 is coated with a sol-gel;

FIG. 6 is a view showing a state in which a transparent member is bonded to the sol-gel in FIG. 5; and

FIG. 7 is a view showing a state in which the substrate and the AAO are removed from the state shown in FIG. 6.

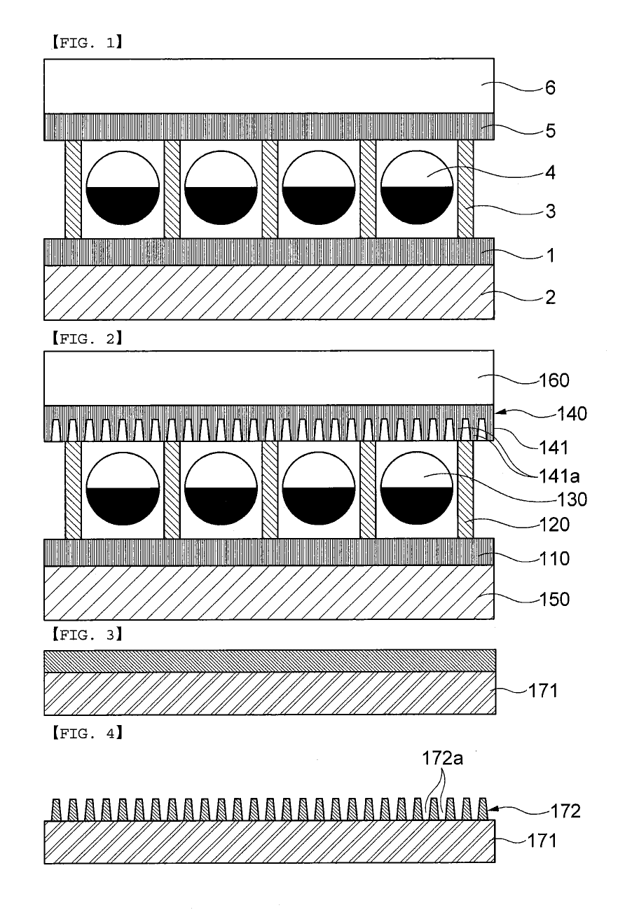

### DESCRIPTION OF THE PREFERRED EMBODIMENTS

Hereinafter, exemplary embodiments of the present invention by which objects of the present invention may be specifically accomplished will be described with reference to the accompanying drawings. In describing the present invention, like components are denoted by like reference numerals in order to help in an overall understanding of the present invention and the description of the same components will not be repeated.

First, an electronic paper display device according to the present invention will be described in more detail with reference to FIG. 2.

FIG. 2 is a cross-sectional view schematically showing an electronic paper display device according to the present invention.

Referring to FIG. 2, an electronic paper display device 100 according to an exemplary embodiment of the present invention may be configured to include a lower electrode 110, a barrier structure 120 provided on the lower electrode 110 and having a plurality of cells 121, a plurality of twist balls 130 provided in each cell 121 of the barrier structure 120, and an upper electrode 140 provided above the plurality of twist balls 130 and having an anti-reflection part 141 having a moth-eye pattern 141a formed in a surface thereof, the surface facing the twist balls.

The lower electrode 110 is formed on a substrate 150 to apply an electric field together with the upper electrode 140, such that the plurality of twist balls 130 are rotated by the electric field formed between the lower electrode 110 and the upper electrode 140. As a result, characters or images are displayed due to a position arrangement of transparent or opaque segments divided based on a central portion of each twist ball 130

Here, the upper electrode 140 may be formed of a conductive film through which light can be transmitted. In other words, the upper electrode 140 may be formed of a transparent conductive film made of indium tin oxide (ITO), a compound of indium and tin oxide.

At this time, the upper electrode 140 may be provided, in a sol-gel shape, on one surface of a glass 160. In other words, the upper electrode 140 is bonded, in a sol-gel form, to one surface of the glass 160 and is then subject to a heat treatment such as annealing in such a state to thereby be provided in the glass 160.

The electronic paper display device 100 according to the present invention has the anti-reflection part 141 having a moth-eye pattern 141a formed on the surface thereof, the surface facing the plurality of twist balls 130, so as to increase light transmittance of the upper electrode 140.

In other words, the light transmittance is increased d by minimizing reflectance of the upper electrode 140, thereby making it possible to remarkably improve external display performance of the electronic paper display device such as improvement in brightness.

In this case, the moth-eye pattern 141a may be formed of a plurality of projections having a nano size. The projection may have a cone shape but is not limited thereto.

Here, the moth-eye pattern 141a may have a nano structure of several tens of nanometers to several hundreds of nanometers or micrometers by way of example, thereby making it possible to reduce reflectance on the surface of the upper electrode 140, that is, on the interface with air.

The effects of the moth-eye are more effective in a pattern having a smaller size than a wavelength of light. The moth-eye pattern, that is, the plurality of projections having a nano size continuously changes refractive index of the incident light to thereby abruptly reduce reflectance on the interface of the upper electrode 140, thereby making it possible to remarkably increase light transmittance.

The electronic paper display device according to the present embodiment molds the anti-reflection part 141 formed integrally with the upper electrode on the interface of the upper electrode 140 and having the moth-eye pattern 141a, instead of anti-reflection film according to the related art formed on the interface of the upper electrode through a separate vacuum deposition process, that is, an ITO film, thereby making it possible to simplify manufacturing processes of the upper electrode having anti-reflection effects and the electronic paper display device including the same, reduce manufacturing costs thereof, and improve productivity.

A method of manufacturing an electronic paper display device according to the present invention will be described in detail with reference to FIGS. 3 to 7.

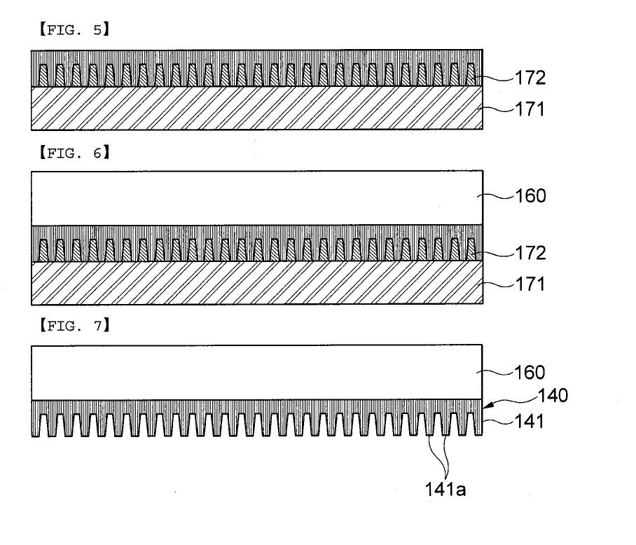

FIGS. 3 to 7 are diagrams for explaining a method of manufacturing an electronic paper display device according to the present invention, wherein FIG. 3 is a view showing a state in which aluminum is deposited on a substrate; FIG. 4 is a view showing a state in which the aluminum deposited in FIG. 3 is anodized to thereby form AAO on the substrate; FIG. 5 is a view showing a state in which the AAO in FIG. 4 is coated with a sol-gel; FIG. 6 is a view showing a state in which a transparent member is bonded to the sol-gel in FIG. 5; and FIG. 7 is a view showing a state in which the substrate and the AAO are removed from the state shown in FIG. 6.

Referring to FIGS. 3 to 7, a method of manufacturing an electronic paper display device according to the present invention may be configured to include forming an anodic aluminum oxide (AAO) 172 on one surface of a substrate 171; coating a sol-gel on the AAO 172, bonding a transparent member 160 to the sol-gel; and removing the substrate 171 and the AAO 172.

In more detail, first as shown in FIG. 3, a metal such as aluminum is deposited on one surface of the substrate 171. In this case, the deposition process may be performed in a sputtering scheme or an e-beam scheme, and the substrate 171 may be formed of a flat transparent member, that is, flat glass.

As shown in FIG. 4, the aluminum deposited on one surface of the substrate 171 is anodized to form the AAO 172 having a moth-eye pattern 172a with a plurality of grooves. In other words, when the aluminum is anodized, the surface of the anodized aluminum is provided with holes having a nano size and regularly arranged thereon. In this case, the holes having a nano size become the moth-eye pattern 172a and the aluminum having the moth-eye pattern 172a becomes the AAO 172 in the present embodiment.

As shown in FIG. 5, a sol-gel is coated on the AAO 172. In this case, the sol-gel may be an indium tin oxide (ITO), a compound of indium and tin oxide, through which light can be transmitted, which is composed in a jelly form. As an example, the sol-gel may be a compound prepared by mixing indium acetylacetonate, tin isopropoxide, and methosyethanol, which is composed in a jelly form. In this case, a spin coating may be performed on the sol-gel, wherein the spin coating may be performed in a vacuum state.

As shown in FIG. 6, a transparent member 160 such as glass is bonded to the sol-gel.

The method of manufacturing the electronic paper display device according to the present embodiment may further include annealing the sol-gel, after the transparent member 160 is bonded to the sol-gel. Here, the annealing of the sol-gel may be performed at a temperature of 400 to 800° C. for 30 to 60 minutes. The annealing of the sol-gel may be performed under an atmosphere of an inert gas such as argon (Ar) or nitrogen (N₂).

As shown in FIG. 7, the substrate 171 and the AAO 172 are removed to thereby form an upper electrode 140 on one surface of the transparent member 160, the upper substrate 140 having the anti-reflection part 141 having the moth-eye pattern 141a with a plurality of projections. In this case, the AAO 172 may be removed by an etching scheme after the substrate 171 is removed. In other words, the AAO 172 is removed by an etching scheme, or the like after the substrate 171 is removed from the state shown in FIG. 6, such that the upper electrode 140 having the anti-reflection part 141 formed of the transparent conductive film made of the indium tin oxide (ITO), through which light can be transmitted, and having the moth-eye pattern 141a with the plurality of projections, is formed integrally with the transparent member 160 bonded to one surface of the upper electrode 140, such as a glass.

With the method of manufacturing the electronic paper display device according to the present embodiment, the anti-reflection part 141 having the moth-eye pattern 141a with the plurality of projections can be formed simultaneously with manufacturing of the upper electrode 140, thereby making it possible to simplify manufacturing processes of the upper electrode having the anti-reflection effects and the electronic paper display device including the same, reduce manufacturing costs thereof, and improve productivity.

As set forth above, with the electronic paper display device and the method of manufacturing the same according to the present invention, the upper electrode can be molded simultaneously with forming the anti-reflection part rather than the anti-reflection coating film is formed on the upper electrode of the electronic paper display device through a separate process, thereby making it possible to simplify the manufacturing process of the upper electrode having an anti-reflection effect and reduce the manufacturing costs thereof.

With the electronic paper display device and the method of manufacturing the same, the manufacturing process of the upper electrode is simplified, thereby making it possible to reduce the manufacturing costs thereof due to the process simplification of the electronic paper display device including the same and improve productivity thereof.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. An electronic paper display device, comprising:
a lower electrode;
twist balls provided in each cell of a barrier structure formed on the lower electrode; and
an upper electrode provided above the twist balls and having an anti-reflection part provided on a surface thereof and having a moth-eye pattern, the surface facing the twist balls.

2. The electronic paper display device according to claim 1, wherein the upper electrode is formed of a transparent conductive film made of indium tin oxide (ITO) through which light is transmitted.

3. The electronic paper display device according to claim 2, wherein the upper electrode is formed, in a sol-gel form, on one surface of a glass.

4. The electronic paper display device according to claim 1, wherein the moth-eye pattern has a nano size.

5. The electronic paper display device according to claim 4, wherein the moth-eye pattern has a cone shape.

6. A method of manufacturing an electronic paper display device, the method comprising:
forming an anodic aluminum oxide (AAO) having a moth-eye pattern with a plurality of grooves by anodizing aluminum deposited on one surface of a substrate;
coating a sol-gel on the AAO;
bonding a transparent member to the sol-gel; and
forming an upper electrode having the anti-reflection part having the moth-eye pattern with a plurality of projections on one surface of the transparent member by removing the substrate and the AAO.

7. The method according to claim 6, wherein the substrate is formed of a flat glass.

8. The method according to claim 6, wherein the aluminum is deposited on the substrate by a sputtering scheme or an e-beam scheme.

9. The method according to claim 6, wherein the moth-eye pattern has a nano size and a cone shape.

10. The method according to claim 6, wherein the sol-gel is prepared by mixing indium acetylacetonate, tin isopropoxide, and methosyethanol.

11. The method according to claim 10, wherein spin coating is performed on the sol-gel.

12. The method according to claim 11, wherein the spin coating is performed in a vacuum state.

13. The method according to claim 6, further comprising annealing the sol-gel, after the bonding of the transparent member to the sol-gel.

14. The method according to claim 13, wherein the annealing of the sol-gel is performed at a temperature of 400 to 800° C. for 30 to 60 minutes.

15. The method according to claim 13, wherein the annealing of the sol-gel is performed under an atmosphere of an inert gas of argon (Ar) or nitrogen (N₂).

16. The method according to claim 6, wherein the removing of the AAO is performed by an etching scheme after the substrate is removed.

17. The method according to claim 6, wherein the upper electrode is formed of a transparent conductive film made of indium tin oxide (ITO) through which light is transmitted.
